(19) United States
(12) Patent Application Publication
(10) Pub. No.: US 2026/0300591 A1
(43) Pub. Date: Oct. 1, 2026

(54) COMPILE TIME REDUCTION AND IMPROVED ROUTABILITY FOR CIRCUIT DESIGNS

(71) Applicant: Xilinx, Inc., San Jose, CA (US)

(72) Inventors: Veeresh Pratap Singh, Hyderabad (IN); Meghraj Kalase, Hyderabad (IN); Madhur Chhabra, Guwahati (IN); Srinivasan Dasasathyan, Hyderabad (IN); Sanjay Saha, Hyderabad (IN); Shail Bains, Hyderabad (IN); Amish Pandya, San Ramon, CA (US)

(73) Assignee: Xilinx, Inc., San Jose, CA (US)

(21) Appl. No.: 19/092,997

(22) Filed: Mar. 27, 2025

(51) Int. Cl. G06F 30/323; G06F 30/392; G06F 30/394

(52) U.S. Cl. CPC G06F 30/323; G06F 30/392; G06F 30/394

(57) ABSTRACT

Compile time reduction and improved routability for circuit designs includes generating, by a first machine learning model and prior to placement, a congestion prediction for a circuit design for an integrated circuit based on a plurality of first features of the circuit design. In response to the congestion prediction indicating congestion of the circuit design, N different implementation strategies for the circuit design are generated. The circuit design is placed and routed using each of the N different implementation strategies.

### TECHNICAL FIELD

This disclosure relates to implementing circuit designs for integrated circuits (ICs) and, more particularly, to reducing compile time and improving routability for circuit designs.

### BACKGROUND

When compiling a circuit design for implementation in an integrated circuit (IC), congestion may be a significant impediment to achieving a successful outcome. Congestion arises when the demand for routing resources to route the circuit design approaches or exceeds the amount of routing resources available in the IC. Congestion may cause the compilation process to run for an unacceptably long period of time or may prevent the compilation process from achieving a feasible implementation of the circuit design. A feasible implementation of a circuit design refers to a placed and routed circuit design that meets established design requirements relating to one or more of timing, power, and/or other requirements. An infeasible implementation refers cases where the placed and routed circuit design does not meet one or more design requirements or where the compilation process fails to place and/or route the circuit design.

Congestion may play an even greater role in the context of emulation and prototyping of circuit designs for Application Specific ICs (ASICs). Because an ASIC circuit design is too large to be prototyped in a single FPGA, the ASIC circuit design is partitioned into multiple partitions. Each partition is treated as a different circuit design that is implemented in a different Field Programmable Gate Array (FPGA) of an emulation system that includes many interconnected FPGAs. To implement each partition in its own FPGA of the emulation system, each partition (e.g., circuit design) must be compiled. In this context, the presence of congestion in any one of the partitions of the larger ASIC circuit design may delay the prototyping process by unduly increasing compilation runtimes or result in a failed attempt at emulating the ASIC circuit design in the emulation system.

### SUMMARY

In one or more examples, a method includes generating, by a first machine learning model and prior to placement, a congestion prediction for a circuit design for an integrated circuit (IC) based on a plurality of first features of the circuit design. The method includes, in response to the congestion prediction indicating congestion of the circuit design, generating N different implementation strategies for the circuit design. The method includes placing and routing the circuit design using each of the N different implementation strategies.

In one or more examples, a system includes a hardware processor and one or more computer-readable storage media storing program instructions to cause the hardware processor to perform operations. The operations include generating, by a first machine learning model and prior to placement, a congestion prediction for a circuit design for an IC based on a plurality of first features of the circuit design. The operations include, in response to the congestion prediction indicating congestion of the circuit design, generating N different implementation strategies for the circuit design. The operations include placing and routing the circuit design using each of the N different implementation strategies.

In one or more examples, a computer program product includes one or more computer-readable storage mediums and program instructions stored on the one or more computer-readable storage mediums to perform operations. The operations include generating, by a first machine learning model and prior to placement, a congestion prediction for a circuit design for an IC based on a plurality of first features of the circuit design. The operations include, in response to the congestion prediction indicating congestion of the circuit design, generating N different implementation strategies for the circuit design. The operations include placing and routing the circuit design using each of the N different implementation strategies.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the implementations to only the examples shown. Various aspects and advantages will become apparent upon review of the following detailed description and upon reference to the drawings.

FIG. 1 illustrates certain operative features of an example computer-based Electronic Design Automation (EDA) tool.

FIG. 2 illustrates an example method of operation for the EDA tool of FIG. 1.

FIG. 3 illustrates an example of a data processing system capable of executing the example EDA tool of FIG. 1.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to implementing circuit designs for integrated circuits (ICs) and, more particularly, to reducing compile time and improving routability for circuit designs. In accordance with the implementations described within this disclosure, methods, systems, and computer program products are provided that are capable of reducing the runtime (e.g., compile time) of circuit design implementation tools. Example implementations described herein provide a computer-based Electronic Design Automation (EDA) tool that is capable of achieving a feasible implementation of a circuit design. The EDA tool is also capable of achieving a feasible implementation of the circuit design in less time than using conventional compilation techniques. Further, the EDA tool is capable of achieving a feasible placement and/or routing solution for a circuit design in cases where conventional compilation techniques may fail to generate a placement or routing solution.

In one or more example implementations, circuit designs may be evaluated prior to placement and/or routing for congestion. Traditionally, congestion has been addressed by extracting congestion hotspots only after placement and/or routing has been performed. Having performed placement and/or routing, conventional approaches perform an analysis on the modules of the circuit design to determine those responsible for the congestion so that changes may be made to the modules prior to a next compilation run or iteration. This conventional approach iterates over multiple compilation runs thereby requiring significant computational resources and time.

By predicting which circuit designs are likely to have congestion and doing so prior to placement and/or routing, the EDA tool is capable of generating one or more implementation strategies prior to placement to address the predicted congestion. The implementation strategies may be applied by the EDA tool to reduce the likelihood of congestion occurring during placement and/or routing. This allows the placer and/or the router to generate respective solutions in less time than would otherwise be the case and often with a greater Quality-of-Result (QoR). In some cases, the QoR may be measured in terms of increased speed of the physical implementation of the circuit design, reduced use of routing resources, reduced complexity in the placement and/or routing solution that is generated, or the like. In other cases, QoR may be measured in terms of reduced compilation runtime while still achieving a feasible placement and/or routing solution. The EDA tool, for example, is capable of achieving a better distribution of components and routing for the circuit design, which facilitates timing closure in less time.

The implementations described within this disclosure are operable on individual circuit designs. In addition, or in the alternative, the implementations described are operable on circuit designs representing individual partitions of a larger circuit design in the context of emulation and prototyping. As an illustrative and non-limiting example, the disclosed technology may be used to implement one or more or all of the partitions of an Application Specific IC (ASIC) circuit design where each partition is compiled as a different circuit design and implemented within a different IC of an emulation system. Such emulation systems may include tens or hundreds of Field Programmable Gate Arrays (FPGAs), for example.

The implementations described herein are capable of reducing the compile time of one or more of the partitioned circuit designs, including the so called “long pole” circuit design of an ASIC circuit design. The long pole circuit design (e.g., partition of the larger circuit design) is the circuit design that takes the longest time to compile. By reducing the compile time of the long pole circuit design, the overall time needed to emulate and/or prototype a given ASIC circuit design in an emulation system may be significantly reduced. Further, the likelihood of success, i.e., achieving a feasible placement and/or routing solution for each partition, is increased.

The implementations described herein are capable of achieving feasible placement and/or routing solutions without attempting a first compilation that does not succeed, only to then continue iterating in the hope of achieving a feasible solution. For purposes of illustration, a circuit design may, in some cases, take 20 or more hours to compile. Given the lengthy time required to compile such a circuit design, any reduction in the compile time, any reduction in the number of iterations required, and any increase in the likelihood of success of compilation can significantly reduce the development time for an IC and reduce the amount of computational resources required to compile the circuit design. These benefits are magnified in the case of emulation and prototyping.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

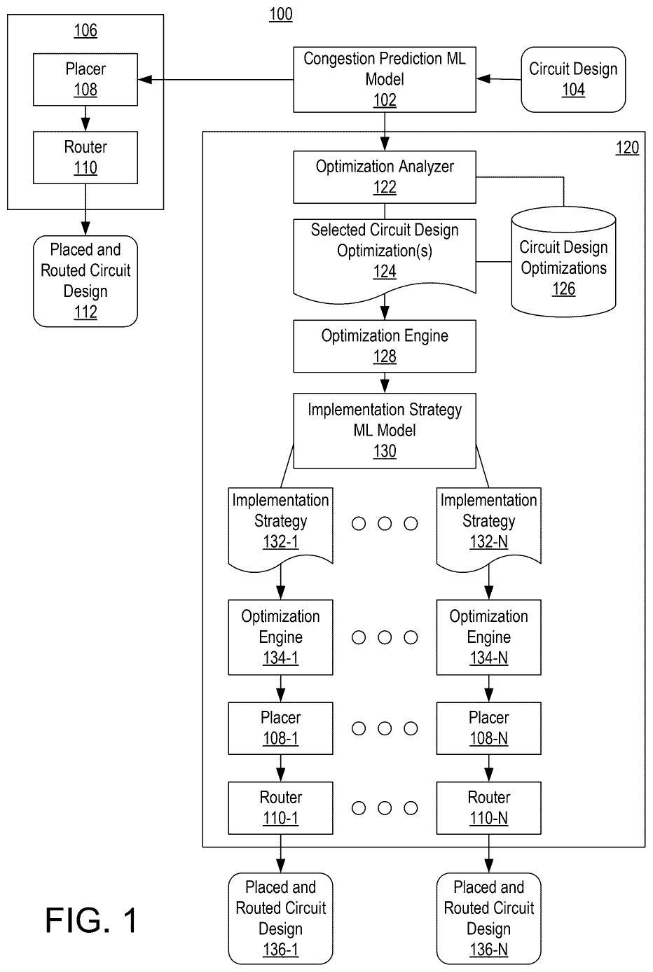

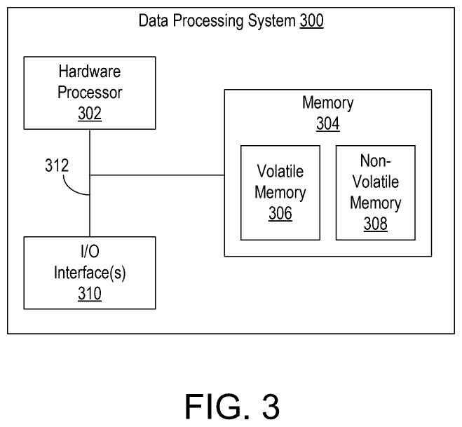

FIG. 1 illustrates certain operative features of an example Electronic Design Automation (EDA) tool 100. EDA tool 100 is an example of a computer-based implementation tool that may be executed by a data processing system, e.g., a computer. EDA tool 100, for example, may be comprised of program instructions that, when executed, perform one or more of the various operations described within this disclosure. An example of a data processing system that may be used to execute EDA tool 100 is described in connection with FIG. 3.

EDA tool 100 is capable of performing a design flow on a circuit design. Implementing a circuit design within an IC, whether a programmable IC or an ASIC, entails processing the circuit design through a multi-stage process referred to as a design flow. Within this disclosure, compiling a circuit design is used interchangeably with one or more or all of the stages of a design flow.

A design flow, or compiling a circuit design, typically entails synthesis, placement, and routing. In general, synthesis refers to the process of generating a gate-level netlist from a high-level description of a circuit or system. The netlist may be technology specific in that the netlist is intended for implementation in a particular IC referred to as a “target IC.” Placement refers to the process of assigning elements of the synthesized circuit design to particular instances of circuit blocks and/or resources having specific locations on the target IC. Routing refers to the process of selecting or implementing particular routing resources, e.g., wires and/or other interconnect circuitry, to electrically couple the various circuit blocks of the target IC after placement. The resulting circuit design, having been processed through the design flow, may be physically realized within the target IC.

In the example of FIG. 1, certain phases of the design flow such as synthesis and/or linking are not illustrated though may be included in, or performed by, EDA tool 100. In the example, EDA tool 100 includes a congestion prediction machine learning (ML) model 102. Based on a congestion prediction generated by congestion prediction ML model 102, EDA tool 100 is capable of processing a circuit design such as circuit design 104 through flow 106 or flow 120. In general, flow 106 represents a standard portion of a design flow in which placement and routing are performed. Flow 120 represents a different portion of a design flow in which different implementation strategies are generated prior to placement and routing and are implemented to avoid or alleviate congestion in circuit design 104 during placement and/or routing.

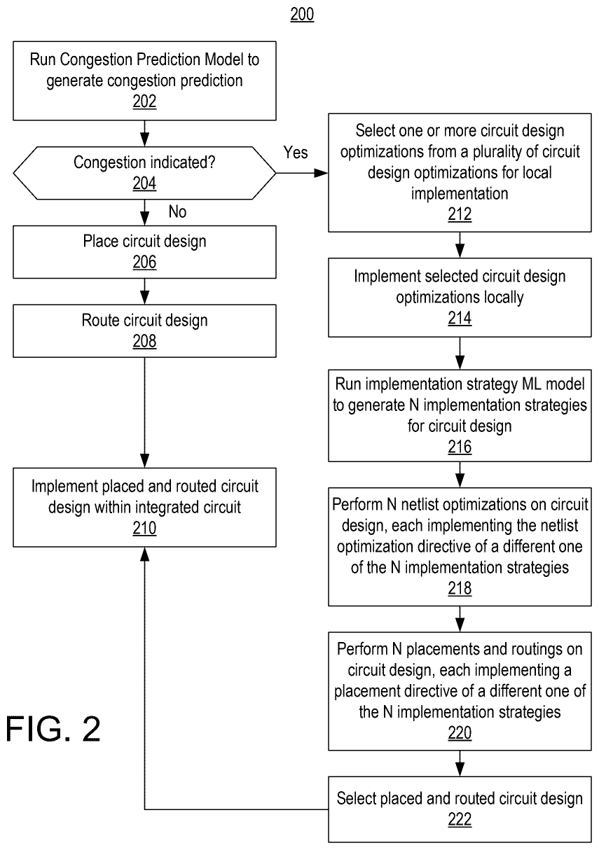

FIG. 2 illustrates an example method 200 of operation for EDA tool 100 of FIG. 1. Referring to FIGS. 1 and 2, circuit design 104 may have undergone synthesis and/or linking. As illustrated in FIG. 1, circuit design 104, which may be specified as a netlist, is provided to congestion prediction ML model 102.

In block 202, congestion prediction ML model 102, also referred to herein as a first ML model, is run on circuit design 104 to generate a congestion prediction. The congestion prediction specifies a likelihood that circuit design 104 will be congested for purposes of performing placement and/or routing. For example, a set of features, e.g., “first features,” may be extracted from circuit design 104 and provided to congestion prediction ML model 102 as input.

Examples of first features that may be extracted from circuit design 104 may include, but are not limited to, utilization of certain circuit resources, e.g., primitives, on the target IC by circuit design 104. For purposes of illustration, utilization may include the number of different lookup tables (LUTs) such as LUT5, LUT6, etc., where the numeral indicates the number of inputs of the LUT primitive, used by circuit design 104. Other examples of first features include the number of nets having a fanout of a certain number or above a certain number (e.g., 4, 5, 6, etc.). Still other examples of first features may include a number of buses in the circuit design and/or a width of each bus in terms of bits. In still other examples, the first features may include a number of pblocks (e.g., floor-planning blocks that include a portion of logic) in circuit design 104.

In one or more examples, congestion prediction ML model 102 is implemented as a random forest model. As generally known, a random forest model implements supervised machine learning and is implemented as an aggregation of multiple decision trees. Each decision tree includes a root node, decision nodes, and leaf nodes. As generally known, the random forest model is trained by performing node splitting to generate the ensemble of decision trees. For each split, features and thresholds are selected that minimizes a metric referred to as the Gini Impurity. The decision trees are grown during training by recursively splitting nodes based on the Gini Impurity until a stopping criterion is met. The stopping criterion may be a maximum depth or a minimum number of samples per leaf, for example.

In one or more implementations, congestion prediction ML model 102 may be trained using a set of training circuit designs that may be labeled to indicate congestion and/or different levels of congestion. In one or more examples, the level of congestion of a training circuit design may be specified as a congestion metric. The congestion metric may reflect or indicate time required to compile the training circuit design. Congestion prediction ML model 102 may be trained to generate a congestion metric for a training circuit design based on one or more or various combinations of the first features as extracted from the training circuit design.

Accordingly, once trained, congestion prediction ML model 102 is capable of generating a prediction (e.g., a congestion metric) indicating a likelihood of congestion occurring during placement and/or routing of circuit design 104 given one or more or various combinations of the first features extracted from circuit design 104. For example, congestion prediction ML model 102 is capable of extracting one or more or various combinations of the first features from circuit design 104 and processing the first features through the ensemble of decision trees of the random forest model. For example, each of the decision tree is capable of generating a probability of circuit design 104 being congested for placement and/or routing. The probabilities from the respective decision trees of congestion prediction ML model 102 may be averaged to generate the congestion prediction that is output from congestion prediction ML model 102.

In block 204, EDA tool 100 decides how to process circuit design 104 based on whether the congestion prediction indicates congestion. For example, in response to the congestion prediction indicating no congestion or an amount of congestion less than a threshold amount, method 200 continues to blocks 206 and 208 of FIG. 2. Blocks 206 and 208 of FIG. 2 correspond to flow 106 of FIG. 1. As noted, flow 106 represents conventional placement and routing processes performed on circuit design 104. In block 206, placer 108 places circuit design 104. In block 208, router 110 routes circuit design circuit design 104 resulting in placed and routed circuit design 112. After block 208, method 200 continues to block 210.

In response to the congestion prediction indicating congestion, method 200 continues to blocks 212-220, which correspond to flow 120 of FIG. 1. In implementing flow 120, EDA tool 100 is capable of generating a plurality (e.g., N) different implementation strategies for circuit design 104. The different implementation strategies are intended to remove or alleviate congestion in circuit design 104 so that placement and routing may be performed more efficiently (e.g., in less time) and/or achieve a greater QoR than would be achieved using flow 106.

For example, in block 212, optimization analyzer 122 is capable of selecting one or more circuit design optimizations 124 from a plurality of circuit design optimizations 126 available as part of EDA tool 100. The circuit design optimization(s) that are selected may be selected based on a local analysis of portion of circuit design 104 and applied locally to such portions of circuit design 104. An example of local analysis and/or local application is one in which individual modules of circuit design 104 (e.g., in reference to the design hierarchy) are evaluated and processed.

In block 212, the selection may be based on a comparison of circuit design 104 with predetermined rules corresponding to different ones of circuit design optimizations 126. For example, each rule may specify one or more conditions that, if found to exist in circuit design 104 or a portion thereof such as a module, cause optimization analyzer 122 to select the circuit design optimization 126. Table 1 illustrates examples of circuit design optimizations 126 from which selected circuit design optimization(s) 124 may be chosen.

TABLE 1

| Circuit Design | |
|---|---|
| Optimization | |
| Identifier | Description |
| 1 | Identifying module(s) of circuit design to |
| | remap selected multiplexers |
| 2 | Lookup table (LUT) decomposition to improve |
| | short congestion |
| 3 | Bloat hierarchical cells of high rent complexity |
| 4 | Uncombine high utilization of combined LUTs |
| | from hierarchical modules |
| 5 | Insert buffer(s) on high fanout nets driving |
| | control signals or local clocks |
| 6 | Apply USER_CROSSING_SLR constraint on nets |
| | driven by selected multiplexers |
| 7 | Replicate high fanout nets that drive only |
| | data pin of loads |
| 8 | Apply USER_SLL_REG constraint on registers |
| | across Super Logic Regions (SLRs) connected |
| | by single fanout nets |
| 9 | Small fanout control set optimization |

In one or more examples, optimization analyzer 122 is capable of iterating over the modules of circuit design 104 that have at least a minimum or pre-defined size. Optimization analyzer 122 is capable of checking modules, e.g., only those having a size greater than or equal to the minimum size, to detect whether one or more or each of circuit design optimizations 1-9 may be performed on that module. Those modules that meet the condition(s) of a rule for any of circuit design optimizations 1-9 may be a source of congestion later. Accordingly, for any module of circuit design 104 having a size greater than or equal to the minimum size that meets a condition of a rule, the circuit design optimization 126 corresponding to the rule is selected to be implemented on the module.

In one or more other examples, optimization analyzer 122 is capable of checking each module of circuit design 104 for applicability of one or more or each of circuit design optimizations 1-9 thereto. In that case, Accordingly, for any module of circuit design 104 that meets a condition of a rule, the circuit design optimization 126 corresponding to the rule is selected to be implemented on the module.

Optimization 1 implements a remapping technique. Optimization 1 searches modules of circuit design 104 for components that are mapped to particular multiplexer primitives that are associated with (e.g., have caused) congestion. Use, or over-use, of such multiplexer primitives may lead to higher routing demand (e.g., congestion) and/or may limit placement flexibility. In one or more examples, optimization 1 may be selected for application to module(s) of circuit design 104 as discussed above in response to detecting at least a minimum number of components mapped to these particular multiplexer primitives in the module(s).

Examples of such multiplexer primitives may include “MUXF” multiplexer primitives that provide benefits in terms of timing criticality and/or reducing logic levels but contribute to increased congestion. High utilization of MUXFs can cause high pin density in certain areas of an IC that can potentially cause high short congestion. Optimization 1 remaps components of circuit design 104 from such multiplexer primitives to other primitives such as lookup tables (LUTs) that do not contribute to congestion. In many cases, the LUTs to which the circuit component may be remapped may be a small LUT such as a 3-input LUT (e.g., LUT3). An example condition existing in a module of circuit design 104 that may cause optimization analyzer 122 to select optimization 1 may be a LUT utilization of the module over a threshold percentage (e.g., 75%) and a MUXF utilization over a different threshold percentage (e.g., 10%).

The term “short congestion” refers to congestion (e.g., high competition for) shorter wires (e.g., routing resources). By comparison, “long congestion” refers to competition for longer wires (e.g., longer routing resources). The target IC will include a variety of different types of wires that may be used to route nets. The wires may be classified as “short” or “long” depending on their length.

Optimization 2 applies a LUT_DEOMPOSE property to selected LUTs to implement LUT decomposition to improve short congestion. Optimization 2 is capable of reducing interconnect density and, in turn, reducing routing congestion without having a significant or appreciable effect on design performance or resource utilization. Optimization 2, for example, is capable of decomposing 5 input LUTs (LUT5) or 6 input LUTs (LUT6) instances into smaller LUTs. An example condition existing in a module of circuit design 104 that may cause optimization analyzer 122 to select optimization 2 may be a utilization of a particular type of LUT such as a LUT6 over a threshold percentage (e.g., 30%).

Optimization 3, also referred to as “cell bloating,” inserts whitespace (increased cell spacing) leading to a lower density of cells in a given area of the die of the target IC. This reduces congestion by increasing available routing. An example condition existing in a module of circuit design 104 that may cause optimization analyzer 122 to select optimization 3 may be detecting an amount of interconnectedness, sometimes referred to as “rent complexity,” of a given module that exceeds a threshold amount. The amount of interconnectedness may be calculated based on a number of input pins and output (I/O) pins of the module. Lower numbers of I/O pins for a module are correlated with higher interconnectedness within the module making placement more difficult. Higher numbers of I/O pins for a module are correlated with lower interconnectedness within the module which is typically easier to place. An example condition existing in a module of circuit design 104 that may cause optimization analyzer 122 to select optimization 3 may be detecting a number of I/Os for the module that does not exceed a threshold number of I/Os.

Optimization 4 uncombines high utilization combined LUTs that may cause high pin density in certain portions of the target IC leading to high congestion. An example condition existing in a module of circuit design 104 that may cause optimization analyzer 122 to select optimization 4 may be detecting that combined LUTs in the module exceed a threshold (e.g., 25%).

Optimization 5 minimizes local routing by making use of global routing. Nets having the highest return in terms of global routing may be limited thereby limiting the number of global nets that may be used. Local clocks, for example, having a large number of loads may be unroutable due to worst hold slack and overall total hold slack which may create an issue for the router to detour so many signals. In such cases, a buffer (e.g., a BUFGCE) may be inserted on the high fanout nets driving control signals or clock signals. An example condition existing in a module of circuit design 104 that may cause optimization analyzer 122 to select optimization 5 may be detecting a high fanout net driving control or clock signals with more than a threshold number of loads (e.g., more than 1,000 loads).

Optimization 6 applies a USER_CROSSING_SLR constraint to particular nets driven by selected multiplexer primitives (e.g., MUXFs) which cross from one die to another. The design constraint prevents the nets from using particular routing resources, referred to as a super long line or “SLL,” that crosses from one die, referred to as a super logic region or “SLR, to another. An example condition existing in a module of circuit design 104 that may cause optimization analyzer 122 to select optimization 6 may be detecting utilization above a particular threshold for SLLs driven by MUXFs where the driver is not a flip-flop.

Optimization 7 deals with very high fanout nets driving only data pins of the loads, which may cause congestion. Optimization 7 applies a FORCE_MAX_FANOUT property that causes replication of drivers of such nets. An example condition existing in a module of circuit design 104 that may cause optimization analyzer 122 to select optimization 7 may be detecting a high fanout net that drives data pins with a fanout exceeding a predetermined threshold.

Optimization 8 applies the USER_SLL_REG constraint to registers across SLRs connected by single fanout nets. USER_SLL_REG instructs the implementation tools to place the registers in particular locations or sites of the IC (e.g., a particular type of register primitive) that is optimal for connections to an SLL. Without this constraint, registers for a net that crosses a die boundary may not be placed in close proximity to the crossing thereby requiring additional routing resources to connect to the SLL which contribute to congestion.

Optimization 9 is capable of remapping small fanout control signals that are often a cause of congestion. In cases where the fanout exceeds a threshold fanout. An example condition existing in a module of circuit design 104 that may cause optimization analyzer 122 to select optimization 9 may be detecting a control signal with a fanout within a defined range. Such control sets on data paths within the defined range may be remapped.

In block 214, optimization engine 128 is capable of implementing the circuit design optimizations selected by optimization analyzer 122. For example, optimization engine 128 is capable of modifying the netlist for circuit design 104 to implement the selected circuit design optimization strategy or strategies for each of the various modules of circuit design 104. In this regard, the optimizations that are selected are applied locally to circuit design 104.

In block 216, implementation strategy ML model 130, e.g., a second ML model, is capable of operating on features (e.g., second features) extracted from circuit design 104 and predicting which of a plurality of different implementation strategies are to be used. In block 216, implementation strategy ML model 130 operates on circuit design 104 post processing in block 214. Implementation strategy ML model 130 is capable of generating N different placer directives as a subset selected from a plurality of placer directives based on the second features of the circuit design. Implementation strategy ML model 130 is also capable of generating N different netlist optimization directives as a subset selected from a plurality of netlist optimization directives based on a second plurality of features of the circuit design.

Each implementation strategy may include a netlist optimization directive, a placer directive, and/or a router directive. Netlist optimization directives are implemented by optimization engine 134 (which may be another instance of optimization engine 128 or a variation of optimization engine 128). Placer directives are implemented by placer 108 in placing circuit design 104. Routing directives, if specified by an implementation strategy, are implemented by router 110 in routing circuit design 104. The features extracted from circuit design 104 and used as input to implementation strategy ML model 130 may be referred to as second features.

Examples of the second features may include, but are not limited to, utilization of particular LUTs (e.g., 6-input LUTs), number of nets with a fanout larger than a threshold fanout (e.g., greater than 500), configurable logic block (CLB) LUT utilization, total number of control sets, soft LUTNM utilization, utilization of selected types of multiplexer primitives (e.g., F7/F8 multiplexer utilization), and/or the runtime consumed by one or more of the optimization phases described herein.

In one or more examples, implementation strategy ML model 130 is implemented as a random forest ML model. The second features, as extracted from circuit design 104, are provided to implementation strategy ML model 130 as input. In one or more examples, implementation strategy ML model 130 is capable of generating a plurality of implementation strategies 132, e.g., the top N implementation strategies 132, where N is an integer value.

In one or more examples, implementation strategy ML model 130 may be trained using a set of training circuit designs where the second features (e.g., as discussed above) are extracted from the training circuit designs and the model is trained to generate N implementation strategies that minimize compile time. In one or more implementations, the set of training circuit designs used to train implementation strategy ML model 130 may be the same as the set used to train congestion prediction ML model 102. In one or more other implementations, the set of training circuit designs used to train implementation strategy ML model 130 may be different from the set used to train congestion prediction ML model 102. The training circuit designs may be processed through a design flow with optimization engine 134 configured to implement particular netlist optimization directives and the placer configured to implement particular placer directives so that implementation strategy ML model 130 learns which netlist optimization directives and placer directives to select for a given set of the second features that is likely to result in a lowest or minimized compilation time (e.g., for performing place and/or route).

Table 2 illustrates an example list of N top implementation strategies 132 that may be generated by implementation strategy ML model 130. In the example, each implementation strategy 132 includes a netlist optimization directive, a placer directive, and a router directive. In the examples, the router directive may be set to “default.” In the example, N=3 though other values of N may be specified. In one or more implementations, N may be a user-specified parameter in EDA tool 100.

TABLE 2

| N | Command | Options |
|---|---|---|
| 1 | opt_design | -hier_fanout_limit 512 |
| | place_design | -directive EarlyBlockPlacement |
| | route_design | -directive Default |
| 2 | opt_design | -merge_equivalent_drivers |
| | place_design | -directive SSI_BalanceSLRs |
| | route_design | -directive Default |
| 3 | opt_design | -directive Default |
| | place_design | -directive Default |
| | route_design | -directive Default |

Each implementation strategy 132 may include any of a variety of available netlist optimization directives and any of a variety of available placer directives within EDA tool 100. Examples of netlist optimization directives that are capable of optimizing (e.g., modifying) the netlist of circuit design 104 from which the top N netlist optimization directives may be selected as a subset by implementation strategy ML model 130 are illustrated in Table 3 below.

TABLE 3

| Optimization Directive | Description |
|---|---|
| merge_equivalent_drivers | Merges equivalent drivers |
| aggressive_remap | Performs remapping |
| hier_fanout_limit 512 | Imposes a fanout limit |
| merge_equivalent_{—} | Combination of merging equivalent |
| drivers -aggressive_remap | drivers and remapping |
| merge_equivalent_drivers -hier_{—} | Combination of merging equivalent |
| fanout_limit 512 | drivers and imposing fanout limit |
| aggressive_remap -hier_{—} | Combination of remapping and |
| fanout_limit 512 | imposing fanout limit |
| merge_equivalent_{—} | Combination of merging equivalent |
| drivers -aggressive_{—} | drivers, remapping, and imposing |
| remap -hier_fanout_limit 512 | fanout limit |
| resynth_seq_area | Performs resynthesis of particular |
| | area |
| resynth_area | Performs resynthesis of particular |
| | area |
| resynth_seq_area -resynth_area | Performs resynthesis of particular |
| | areas |
| resynth_seq_area -aggressive_{—} | Combination of resynthesis of |
| remap | particular area and remapping |
| resynth_area -aggressive_remap | Combination of resynthesis of |
| | particular area and remapping |
| resynth_seq_area -resynth_{—} | Combination of resynthesis of |
| area -aggressive_remap | particular areas and remapping |

Examples of placer directives that may be implemented by the placer while placing circuit design 104 from which the top N placer directives may be selected as a subset by implementation strategy ML model 130 are illustrated in Table 4 below.

TABLE 4

| | |
|---|---|
| AltSpreadLogic_high | Spreads logic throughout the device to |
| | avoid creating congested regions (high |
| | level of spreading). |
| EarlyBlockPlacement | Timing-driven placement of RAM and |
| | DSP blocks. The RAM and DSP block |
| | locations are finalized early in the |
| | placement process and are used as |
| | anchors to place the remaining logic. |
| AltSpreadLogic_medium | Spreads logic throughout the device to |
| | avoid creating congested regions |
| | (medium level of spreading). |
| SSI_BalanceSLRs | Partition across SLRs to balance number |
| | of cells between SLRs. |
| SSI_BalanceSLLs | Partition across SLRs while attempting to |
| | balance SLLs between SLRs. |
| SSI_SpreadLogic_high | Spreads logic throughout the SSI device |
| | to avoid creating congested regions. |
| SSI_HighUtilSLRs | Force the placer to attempt to place logic |
| | closer together in each SLR. |
| WLDrivenBlockPlacement | Wirelength-driven placement of RAM |
| | and DSP blocks. |
| ExtraNetDelay_low | Increases estimated delay of high fanout |
| | and long-distance nets. |

The example directives illustrated in Tables 3 and 4 are provided for purposes of illustration only. It should be appreciated that any netlist optimization and/or placer directive available within EDA tool 100 may be considered for selection within an implementation strategy so long as implementation strategy ML model 130 is trained to consider such a directive.

In block 216, in running implementation strategy ML model 130, EDA tool 100 is capable of generating N implementation strategies 132. Each of the N implementation strategies 132 may be different. In one or more examples, each implementation strategy 132 includes one or more of the netlist optimization directives of Table 3 and one of the placer directives from Table 4 as determined by implementation strategy ML model 130. In one or more examples, each of the N implementation strategies 132 will include a different (e.g., unique) netlist optimization directive and a different (e.g., unique) placer directive. In one or more other examples, two or more of the N implementation strategies 132 may include a same netlist optimization directive but each of the N implementation strategies includes a different (e.g., unique) placer directive.

In one or more examples, each of the N implementation strategies 132 may be performed concurrently, e.g., in parallel. Each may be performed in a different process whether in one computer or in different interconnected computers. The circuit design, as processed through optimization engine 128, for example, may be copied and/or provided to each of a plurality of different processes each corresponding to, or implementing, a different one of the N implementation strategies 132.

Accordingly, in block 218, EDA tool 100 is capable of performing N netlist optimizations on the circuit design. Each of the N optimizations may be performed in a different process where each process implements the netlist optimization of a different one of the N implementation strategies. For example, optimization engine 134-1 performs the netlist optimization specified in implementation strategy 132-1. Optimization engine 134-N performs the netlist optimization specified in implementation strategy 132-N.

In block 220, EDA tool 100 is capable of performing N different placements and routings on the circuit design. Each placement and routing may be performed in a different process as described in connection with block 218 (e.g., concurrently or in parallel). Each process implements the placer directive of the particular implementation strategy 132 being implemented. For example, placer 108-1 places the circuit design using the placer directive specified in implementation strategy 132-1. Router 110-1 routes the circuit design as placed by placer 108-1. Placer 108-N places the circuit design using the placer directive specified in implementation strategy 132-N. Router 110-N routes the circuit design as placed by placer 108-1.

In the example, the various operations described may be performed by different instances of the respective blocks (e.g., of optimization engine 134, placer 108, and router 110).

Each of the N different implementation strategies 132 for the different processes illustrated generates a different placed and routed circuit design 136. In block 222, one of the placed and routed circuit designs 136 is selected for use. The selected placed and routed circuit design may be selected based on runtime (e.g., the runtime required to implement or perform the implementation strategy). In one or more examples, EDA tool 100 is capable of selecting the particular placed and routed circuit design 136 that is generated first in time (e.g., the particular placed and routed circuit design from the compilation process that completes first or has the shortest runtime). Further, only a process that results in a successfully implemented (e.g., placed and routed) circuit design is chosen. In one or more examples, in response to completion of the placement and routing by a given process using a given implementation strategy 132, EDA tool 100 may select that placed and routed circuit design 136 and terminate the other processes (e.g., terminate the other placement and routing operations using the other implementation strategies).

In block 210, the placed and routed circuit design, whether placed and routed circuit design 112 as generated by flow 106 or a selected placed and routed circuit design 136 from flow 120, may be implemented in the IC. For example, the configuration data that is generated by flow 106 or flow 120 may be loaded into the IC thereby physically implementing circuit design 104 therein.

In one or more other examples, certain portions of FIG. 2 may be omitted or implemented differently. User preferences may be set in EDA tool 100 that cause one or more portions of FIG. 2 to be omitted (e.g., skipped) or replaced with other user-specified optimization techniques. As an illustrative and non-limiting example, operation of blocks 212 and 214 may be skipped based on user preferences. In another example, one or more other user-specified optimizations may be performed in blocks 212 and 214 in lieu of the examples provided.

FIG. 3 illustrates an example of a data processing system 300. As used herein, a “data processing system” refers to one or more hardware systems capable of processing data. Each hardware system may include one or more hardware processors and memory.

Data processing system 300 includes a hardware processor 302. Hardware processor 302 may be implemented as one or more hardware processors. Hardware processor 302 may be implemented as one or more circuits capable of executing computer-readable program instructions (program instructions). The circuit(s) may comprise integrated circuits (ICs) or may be embedded within an IC. In one or more examples, hardware processor 302 may be embodied as a central processing unit (CPU). Hardware processor 302 may include one or more cores, for example, where each core is capable of executing computer-readable program instructions. Hardware processor 302 may be implemented using any of a variety of architectures such as, for example, a complex instruction set computer architecture (CISC), a reduced instruction set computer architecture (RISC), a vector processing architecture, or other known architectures. For example, a hardware processor may be implemented using an x86 architecture (e.g., IA-32, IA-64), a Power Architecture, as an ARM processor, or the like.

Data processing system 300 can include memory 304. Memory 304 may be embodied as one or more computer-readable storage mediums. Memory 304 may include a volatile memory 306 and a non-volatile memory 308. Volatile memory 306 may be embodied as random-access memory (RAM) and may include cache memory. Volatile memory 306 may be referred to as “runtime memory.” Non-volatile memory 308 may include a non-volatile magnetic medium and/or a solid-state medium (typically called a “hard drive”). Non-volatile memory 308 also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 304 is capable of storing program instructions and/or data such that hardware processor 302 is capable of executing the program instructions to perform one or more operations as described within this disclosure. For example, the program instructions can include an operating system, one or more application programs, other program code, and program data. In one or more implementations, memory 304 is capable of storing EDA tool 100 such that hardware processor 302 executes EDA tool 100 to perform the various operations described herein.

Data processing system 300 may include one or more Input/Output (I/O) interfaces 310. I/O interface(s) 310 allow data processing system 300 to communicate with one or more external devices and/or communicate over one or more networks such as a local area network (LAN), a wide area network (WAN), and/or a public network (e.g., the Internet). Examples of I/O interfaces 310 may include, but are not limited to, network cards, modems, network adapters (wired and/or wireless), hardware controllers, etc. Examples of external devices also may include devices that allow a user to interact with data processing system 300 (e.g., a display, a keyboard, and/or a pointing device) and/or other devices such as an accelerator card.

Bus 312 represents one or more of any of a variety of communication bus structures. By way of example, and not limitation, bus 312 may be implemented as a Peripheral Component Interconnect Express (PCIe) bus. Bus 312 couples to each of hardware processor 302, memory 304, and I/O interface(s) 310 through respective interface circuitry thereby allowing the devices to communicate. Bus 312 may represent a plurality of buses that may be interconnected and/or hierarchically organized.

Data processing system 300 is only one example implementation. Data processing system 300 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. These services may utilize any of a variety of virtualization technologies. Cloud computing promotes availability and may be characterized by on-demand self-service, broad network access, resource pooling, rapid elasticity, and measured service.

The example of FIG. 3 is not intended to suggest any limitation as to the scope of use or functionality of example implementations described herein. Data processing system 300 is an example of computer hardware that is capable of performing the various operations described within this disclosure. In this regard, data processing system 300 may include fewer components than shown or additional components not illustrated in FIG. 3 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc., may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the implementations described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the implementations described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the implementations described herein.

Certain aspects of the implementations are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the implementations. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various implementations of the disclosed technology have been presented for purposes of illustration, but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A method, comprising:
generating, by a first machine learning model and prior to placement, a congestion prediction for a circuit design for an integrated circuit based on a plurality of first features of the circuit design;
in response to the congestion prediction indicating congestion of the circuit design, generating N different implementation strategies for the circuit design; and
placing and routing the circuit design using each of the N different implementation strategies.

2. The method of claim 1, further comprising:
selecting a circuit design implementation resulting from one of the N different implementation strategies based on runtime.

3. The method of claim 1, wherein the congestion prediction indicates whether the circuit design is likely to be congested for at least one of performing placement or performing routing in an implementation flow.

4. The method of claim 1, further comprising:
selecting one or more circuit design optimizations from a plurality of circuit design optimizations based on a comparison of the circuit design with rules corresponding to the plurality of circuit design optimizations; and
performing the one or more circuit design optimizations as selected on the circuit design subsequent to the congestion prediction and prior to the generating the N different implementation strategies.

5. The method of claim 1, wherein the generating the N different implementation strategies comprises:
generating, by a second machine learning model, N different placer directives as a subset selected from a plurality of placer directives based on a second plurality of features of the circuit design;
wherein each of the N different implementation strategies includes a different one of the N different placer directives.

6. The method of claim 5, wherein the generating the N different implementation strategies comprises:
generating, by a second machine learning model, N different netlist optimization directives as a subset selected from a plurality of netlist optimization directives based on a second plurality of features of the circuit design;
wherein each of the N different implementation strategies includes one or more of the N different netlist optimization directives.

7. The method of claim 5, wherein the second machine learning model is trained using a set of training circuit designs to select one or more placer directives that result in a lowest runtime for a given set of the second plurality of features extracted from the training circuit designs.

8. A system, comprising:
a hardware processor; and
one or more computer-readable storage media storing program instructions to cause the hardware processor to perform operations comprising:
generating, by a first machine learning model and prior to placement, a congestion prediction for a circuit design for an integrated circuit based on a plurality of first features of the circuit design;
in response to the congestion prediction indicating congestion of the circuit design, generating N different implementation strategies for the circuit design; and
placing and routing the circuit design using each of the N different implementation strategies.

9. The system of claim 8, wherein the operations comprise:
selecting a circuit design implementation resulting from one of the N different implementation strategies based on runtime.

10. The system of claim 8, wherein the congestion prediction indicates whether the circuit design is likely to be congested for at least one of performing placement or performing routing in an implementation flow.

11. The system of claim 8, wherein the generating the N different implementation strategies comprises:
selecting one or more circuit design optimizations from a plurality of circuit design optimizations based on a comparison of the circuit design with rules corresponding to the plurality of circuit design optimizations; and
performing the one or more circuit design optimizations as selected on the circuit design subsequent to the congestion prediction and prior to the generating the N different implementation strategies.

12. The system of claim 8, wherein the generating the N different implementation strategies comprises:
generating, by a second machine learning model, N different placer directives as a subset selected from a plurality of placer directives based on a second plurality of features of the circuit design;
wherein each of the N different implementation strategies includes a different one of the N different placer directives.

13. The system of claim 12, wherein the generating the N different implementation strategies comprises:
generating, by a second machine learning model, N different netlist optimization directives as a subset selected from a plurality of netlist optimization directives based on a second plurality of features of the circuit design;
wherein each of the N different implementation strategies includes one or more of the N different netlist optimization directives.

14. The system of claim 12, wherein the second machine learning model is trained using a set of training circuit designs to select one or more placer directives that result in a lowest runtime for a given set of the second plurality of features extracted from the training circuit designs.

15. A computer program product comprising:
one or more computer-readable storage media; and
program instructions stored on the one or more computer-readable storage media to perform operations comprising:
generating, by a first machine learning model and prior to placement, a congestion prediction for a circuit design for an integrated circuit based on a plurality of first features of the circuit design;
in response to the congestion prediction indicating congestion of the circuit design, generating N different implementation strategies for the circuit design; and
placing and routing the circuit design using each of the N different implementation strategies.

16. The computer program product of claim 15, wherein the operations comprise:
selecting a circuit design implementation resulting from one of the N different implementation strategies based on runtime.

17. The computer program product of claim 15, wherein the congestion prediction indicates whether the circuit design is likely to be congested for at least one of performing placement or performing routing in an implementation flow.

18. The computer program product of claim 15, wherein the generating the N different implementation strategies comprises:
selecting one or more circuit design optimizations from a plurality of circuit design optimizations based on a comparison of the circuit design with rules corresponding to the plurality of circuit design optimizations; and
performing the one or more circuit design optimizations as selected on the circuit design subsequent to the congestion prediction and prior to the generating the N different implementation strategies.

19. The computer program product of claim 15, wherein the generating the N different implementation strategies comprises:
generating, by a second machine learning model, N different placer directives as a subset selected from a plurality of placer directives based on a second plurality of features of the circuit design;
wherein each of the N different implementation strategies includes a different one of the N different placer directives.

20. The computer program product of claim 15, wherein the generating the N different implementation strategies comprises:
generating, by a second machine learning model, N different netlist optimization directives as a subset selected from a plurality of netlist optimization directives based on a second plurality of features of the circuit design;
wherein each of the N different implementation strategies includes one or more of the N different netlist optimization directives.
